(19) United States
(12) Patent Application Publication
(10) Pub. No.: US 2024/0297625 A1
(43) Pub. Date: Sep. 5, 2024

(54) AMPLIFIER BIASING FOR CLASS-AB OUTPUT STAGE IN A TRANSIMPEDANCE AMPLIFIER (TIA)-BASED LOW-PASS FILTER FOR A PASSIVE UPCONVERTER

(71) Applicant: QUALCOMM INCORPORATED, SAN DIEGO, CA (US)

(72) Inventors: Sadia AFROZ, Fremont, CA (US); Conor DONOVAN, Oakland, CA (US)

(21) Appl. No.: 18/177,164

(22) Filed: Mar. 2, 2023

(51) Int. Cl. H03F 3/45; H03F 1/22; H03F 1/26; H03F 1/56

(52) U.S. Cl. CPC H03F 3/45192; H03F 1/223; H03F 1/26; H03F 1/565; H03F 2200/451

(57) ABSTRACT

A transimpedance-based baseband filter (BBF) including a two-stage operational transconductance amplifier (OTA) having a first stage based on a folded cascode topology, the first stage electrically coupled to a second stage, the second stage having a class AB topology, the first stage having an N-type and P-type transistor pair located between a P-type transistor and an N-type transistor, the N-type and P-type transistor pair configured to provide bias signals to push-pull transistors in the second stage.

### FIELD

The present disclosure relates generally to electronics, and more specifically to amplifier biasing in transceivers.

### BACKGROUND

Wireless communication devices and technologies are becoming ever more prevalent, as are communication devices that operate at 5G NR Sub7 FR1 and millimeter-wave (mmW) FR2 frequencies. Wireless communication devices generally transmit and/or receive communication signals. In a radio frequency (RF) transceiver, a communication signal is typically amplified and transmitted by a transmit section and a received communication signal is amplified and processed by a receive section. A communication device may include multiple transmitters, receivers and antennas and may be capable of communicating on licensed and on unlicensed communication bands and frequencies.

Such communication devices may be configured to communicate via a wireless local-area technology, such as a Bluetooth, a Wi-Fi (IEEE 802.11), or an industrial, scientific or medical network (ISM) network. As governmental authorities generally do not allocate wireless local-area communication frequency bands to specific entities, the frequency bands associated with such technologies are commonly referred to as “unlicensed” communication spectrum, also referred to as unlicensed frequency bands. In contrast, communication spectrum and frequency bands associated with wide-area wireless communication technologies are commonly referred to as “licensed” communication spectrum, or licensed frequency bands, because they are generally allocated to specific entities by governmental authorities.

It would be desirable to share components when implementing a communication device that may communicate using both licensed (e.g., WLAN) and unlicensed (e.g., Bluetooth) frequency bands.

### SUMMARY

Various implementations of systems, methods and devices within the scope of the appended claims each have several aspects, no single one of which is solely responsible for the desirable attributes described herein. Without limiting the scope of the appended claims, some prominent features are described herein.

Details of one or more implementations of the subject matter described in this specification are set forth in the accompanying drawings and the description below. Other features, aspects, and advantages will become apparent from the description, the drawings, and the claims. Note that the relative dimensions of the following figures may not be drawn to scale.

One aspect of the disclosure provides a transimpedance-based baseband filter (BBF) including a two-stage operational transconductance amplifier (OTA) having a first stage based on a folded cascode topology, the first stage electrically coupled to a second stage, the second stage having a class AB topology, the first stage having an N-type and P-type transistor pair located between a P-type transistor and an N-type transistor, the N-type and P-type transistor pair configured to provide bias signals to push-pull transistors in the second stage.

Another aspect of the disclosure provides a method for signal conversion including passively upconverting a wireless local area network (WLAN) communication signal, passively upconverting a Bluetooth (BT) communication signal, selectively amplifying the passively upconverted WLAN communication signal using a common amplifier, and selectively amplifying the passively upconverted BT communication signal using the common amplifier.

Another aspect of the disclosure provides a device including means for passively upconverting a wireless local area network (WLAN) communication signal, means for passively upconverting a Bluetooth (BT) communication signal, means for selectively amplifying the passively upconverted WLAN communication signal, and means for selectively amplifying the passively upconverted BT communication signal.

Another aspect of the disclosure provides a transmit circuit including Bluetooth (BT) communication circuitry comprising a passive BT upconverter (BT UPC) coupled to a load, wireless local area network (WLAN) communication circuitry comprising a passive WLAN upconverter (WLAN UPC) coupled to the load, and a voltage-mode baseband filter (BBF) having an operational transconductance amplifier (OTA) configured to provide a voltage input signal to the BT UPC.

### BRIEF DESCRIPTION OF THE DRAWINGS

In the figures, like reference numerals refer to like parts throughout the various views unless otherwise indicated. For reference numerals with letter character designations such as “102a” or “102b”, the letter character designations may differentiate two like parts or elements present in the same figure. Letter character designations for reference numerals may be omitted when it is intended that a reference numeral encompass all parts having the same reference numeral in all figures.

FIG. 1 is a diagram showing a wireless device communicating with a wireless communication system.

FIG. 2A is a block diagram showing a wireless device in which exemplary techniques of the present disclosure may be implemented.

FIG. 2B is a block diagram showing a wireless device in which exemplary techniques of the present disclosure may be implemented.

FIG. 2C is a block diagram showing a wireless device in which exemplary techniques of the present disclosure may be implemented.

FIG. 3 is a diagram showing an upconverter circuit in accordance with an exemplary embodiment.

FIG. 4A is a diagram showing an operational amplifier circuit used in a baseband filter of FIG. 3.

FIG. 4B is a diagram showing an alternative exemplary embodiment of the operational amplifier circuit of FIG. 4A.

FIG. 5 is a diagram showing some of the bias voltage circuits used in FIG. 4A and FIG. 4B.

FIG. 6 is a flow chart describing an example of the operation of a method for signal upconversion.

FIG. 7 is a functional block diagram of an apparatus for signal upconversion.

### DETAILED DESCRIPTION

The word “exemplary” is used herein to mean “serving as an example, instance, or illustration.” Any aspect described herein as “exemplary” is not necessarily to be construed as preferred or advantageous over other aspects.

In many wireless radio transmitters, a power amplifier and matching circuitry (also referred to as a load) may be shared by multiple circuitry elements. For example, a power amplifier may be shared by a wireless local area network (WLAN) circuitry and by Bluetooth (BT) circuitry Advantages of sharing the same load by the upconverter/mixers (UPC) of both WLAN and Bluetooth transmit paths include reduced area and complexity. A Bluetooth UPC may be implemented as a Gilbert-cell based active mixer driven by a baseband filter (BBF) where the baseband filter operates in a current mode to operate the mixer. Bluetooth communication circuitry implements low bandwidth (BW) (e.g., DC to 5 Mhz max) with high gain resolution (to provide fine tuning of output power) from the baseband filter. In contrast, certain implementations of WLAN communication circuitry may use a passive UPC, which is driven by a voltage mode baseband filter. The input of the mixer is voltage and is typically implemented a transimpedance (TIA)-based filter. The TIA-based filter provides lower power consumption and high UPC linearity for WLAN communication. However, a TIA-based BBF imposes some challenges when the load (matching circuit and power amplifier) is shared by both WLAN circuitry (WLAN UPC for example) and by Bluetooth circuitry (BT UPC for example) because a passive UPC (for WLAN) uses a series inductive (L), capacitive (C) (LC) resonant network. In contrast, an active UPC (for BT) uses a parallel resonance LC network. Thus, a relatively large inductor is implemented by a WLAN UPC to provide the needed series LC resonance at 2.4 GHZ, resulting in the need for a small capacitor in parallel to achieve a parallel resonance in BT mode at the same frequency. This leads to a significant drawbacks in BT mode because the parallel resonance LC network becomes vulnerable to parasitics due to the high Q of the resonant network particularly at the BT bandwidth of DC to 5 MHz. In addition, the tunning becomes problematic and has a narrow adjustment range

A Bluetooth (BT) communication signal typically has a frequency bandwidth from 0 (DC) to approximately 2.5 MHz. However, certain transimpedance amplifier (TIA)-based baseband filters generally may not support such a frequency bandwidth, particularly at low frequencies close to DC Also, high linearity is also desired for a BT communication signal.

In the past, a TIA used Class AB operation and AC coupling capacitors to achieve such desired high linearity. However, large AC coupling capacitors cause a high-pass filter characteristic (e.g., a cutoff frequency of about 200 kHz even with a large capacitance), which may be challenging for BT signal upconversion

In an exemplary embodiment, a BT transmitter may use a passive upconverter (UPC) driven by a voltage mode TIA-based filter. In this arrangement, the BT upconverter can share the same LC load used by a WLAN upconverter. Such an arrangement can reduce the complexity of the shared load network including removing switches and some passive components and may improve the linearity of the WLAN upconverter and the BT upconverter.

In an exemplary embodiment, a TIA-based BBF having high resolution in gain step and the ability to process communications signals down to 0 Hz (DC) low bandwidth may be implemented with a passive BT upconverter

In an exemplary embodiment, the TIA-based baseband filter may implement a biasing methodology for biasing the second stage PMOS and NMOS transistors that does not use AC coupling capacitances between a first stage and a second stage of the TIA, thus eliminating the drawbacks of such AC coupling capacitances.

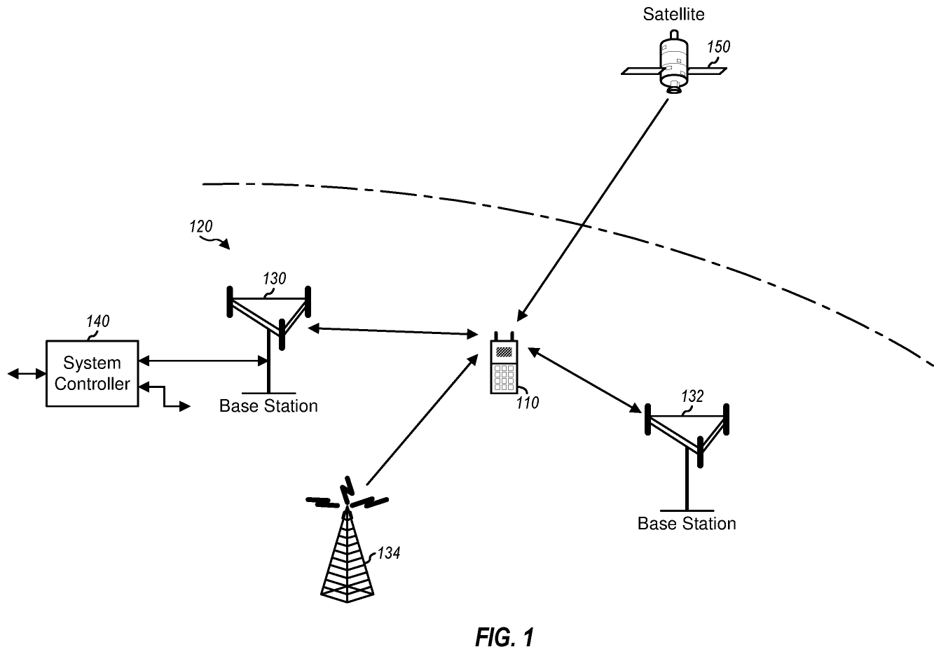

FIG. 1 is a diagram showing a wireless device 110 communicating with a wireless communication system 120. The wireless communication system 120 may be a Long Term Evolution (LTE) system, a Code Division Multiple Access (CDMA) system, a Global System for Mobile Communications (GSM) system, a wireless local area network (WLAN) system, a 5G NR (new radio) system, or some other wireless system. A CDMA system may implement Wideband CDMA (WCDMA), CDMA 1X, Evolution-Data Optimized (EVDO), Time Division Synchronous CDMA (TD-SCDMA), or some other version of CDMA. For simplicity, FIG. 1 shows wireless communication system 120 including two base stations 130 and 132 and one system controller 140. In general, a wireless communication system may include any number of base stations and any set of network entities.

The wireless device 110 may also be referred to as a user equipment (UE), a mobile station, a terminal, an access terminal, a subscriber unit, a station, etc. Wireless device 110 may be a cellular phone, a smartphone, a tablet, a wireless modem, a personal digital assistant (PDA), a handheld device, a laptop computer, a smartbook, a netbook, a tablet, a cordless phone, a medical device, an automobile, a device configured to connect to one or more other devices (for example through the internet of things), a wireless local loop (WLL) station, a Bluetooth device, etc. Wireless device 110 may communicate with wireless communication system 120. Wireless device 110 may also receive signals from broadcast stations (e.g., a broadcast station 134) and/or signals from satellites (e.g., a satellite 150 in one or more global navigation satellite systems (GNSS)), etc.). Wireless device 110 may support one or more radio technologies for wireless communication such as LTE, WCDMA, CDMA 1X, EVDO, TD-SCDMA, GSM, 802.11, 802.15, 5G, Sub6 5G, 6G, UWB, etc.

Wireless device 110 may support carrier aggregation, for example as described in one or more LTE or 5G standards. In some embodiments, a single stream of data is transmitted over multiple carriers using carrier aggregation, for example as opposed to separate carriers being used for respective data streams. Wireless device 110 may be able to operate in a variety of communication bands including, for example, those communication bands used by LTE, WiFi, 5G or other communication bands, over a wide range of frequencies. Wireless device 110 may also be capable of communicating directly with other wireless devices without communicating through a network.

In general, carrier aggregation (CA) may be categorized into two types-intra-band CA and inter-band CA. Intra-band CA refers to operation on multiple carriers within the same band. Inter-band CA refers to operation on multiple carriers in different bands.

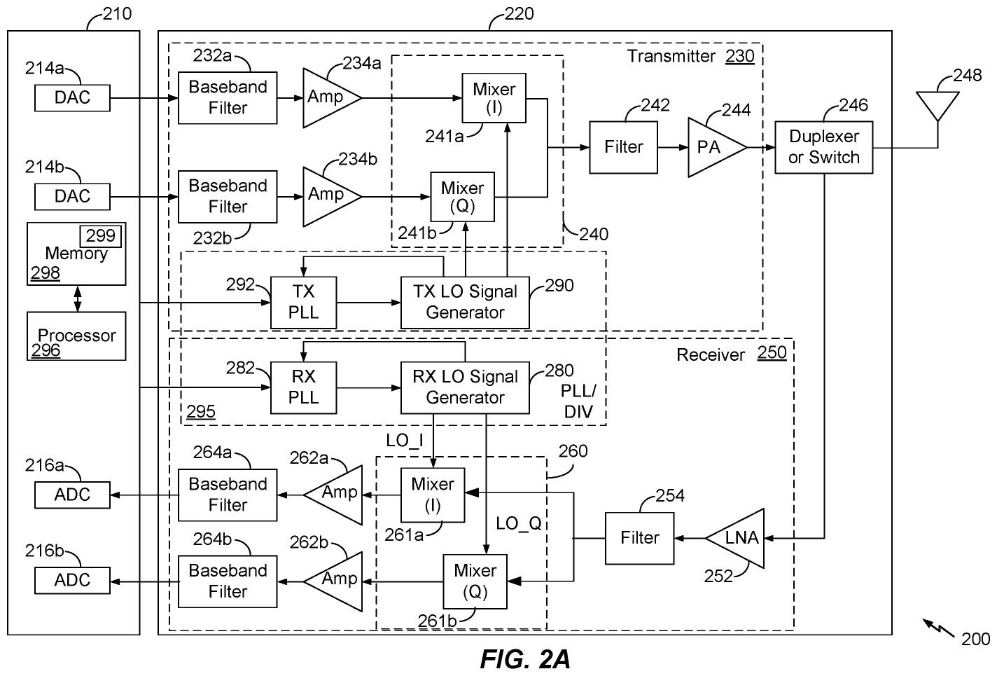

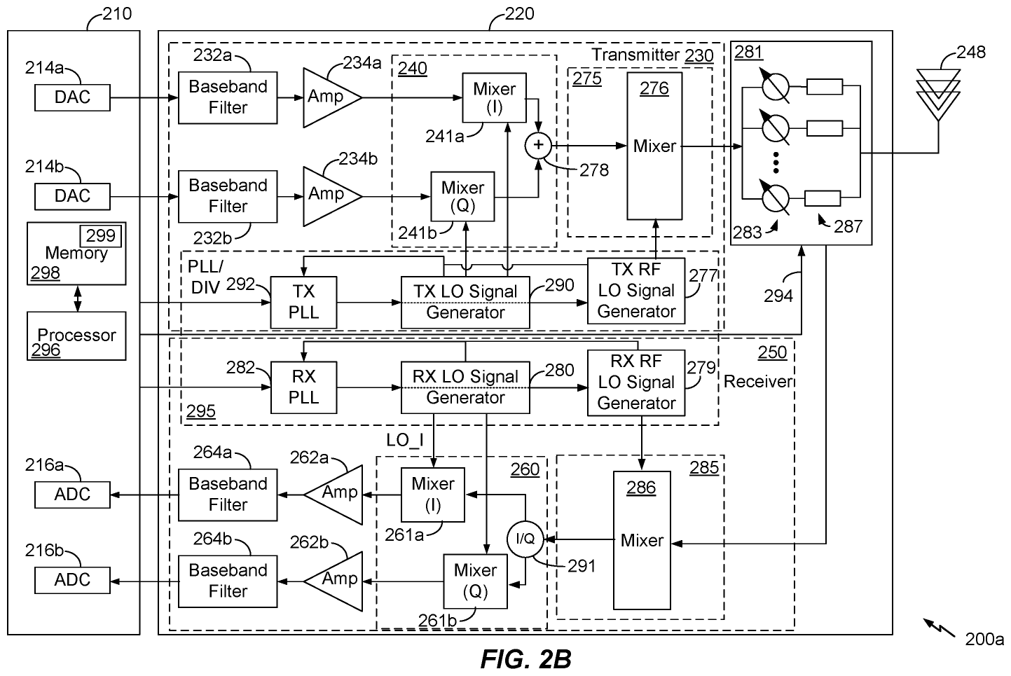

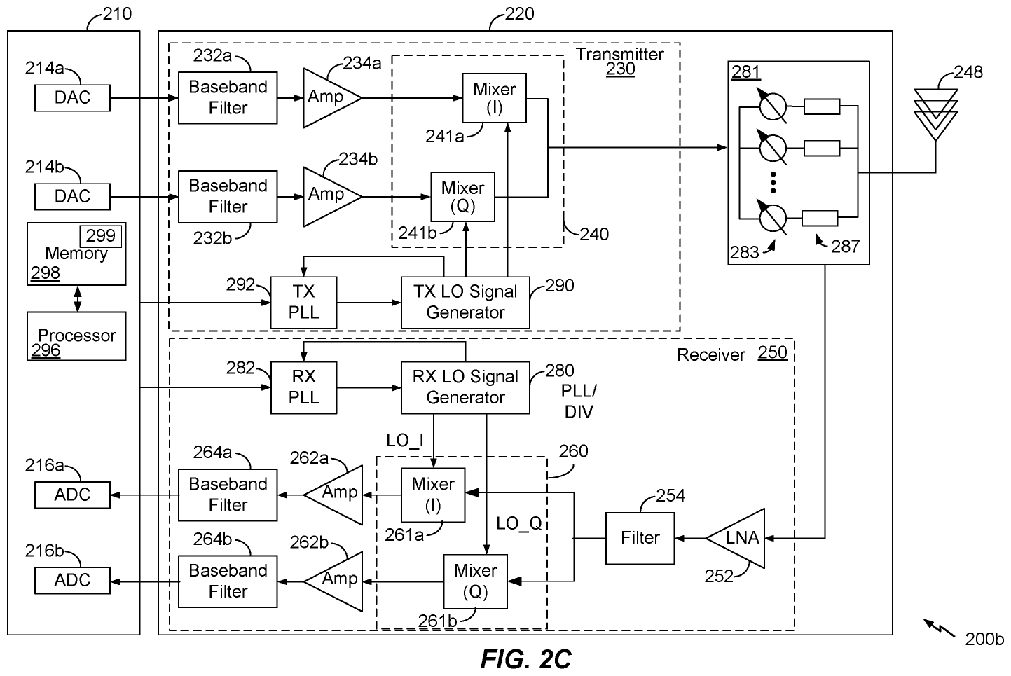

FIG. 2A is a block diagram showing a wireless device 200 in which the exemplary techniques of the present disclosure may be implemented. The wireless device 200 may, for example, be an embodiment of the wireless device 110 illustrated in FIG. 1.

FIG. 2A shows an example of a transceiver 220 having a transmitter 230 and a receiver 250. In general, the conditioning of the signals in the transmitter 230 and the receiver 250 may be performed by one or more stages of amplifier, filter, upconverter, downconverter, etc. These circuit blocks may be arranged differently from the configuration shown in FIG. 2A. Furthermore, other circuit blocks not shown in FIG. 2A may also be used to condition the signals in the transmitter 230 and receiver 250, for example phase shifters as discussed further below. Unless otherwise noted, any signal in FIG. 2A, or any other figure in the drawings, may be either single-ended or differential. Some circuit blocks in FIG. 2A may also be omitted.

In the example shown in FIG. 2A, wireless device 200 generally comprises the transceiver 220 and a data processor 210. The data processor 210 may include a processor 296 operatively coupled to a memory 298. The memory 298 may be configured to store data and program codes shown generally using reference numeral 299, and may generally comprise analog and/or digital processing components. The transceiver 220 includes a transmitter 230 and a receiver 250 that support bi-directional communication. In general, wireless device 200 may include any number of transmitters and/or receivers for any number of communication systems and frequency bands. All or a portion of the transceiver 220 may be implemented on one or more analog integrated circuits (ICs), RF ICs (RFICs), mixed-signal ICs, etc.

A transmitter or a receiver may be implemented with a super-heterodyne architecture or a direct-conversion architecture. In the super-heterodyne architecture, a signal is frequency-converted between radio frequency (RF) and baseband in multiple stages, e.g., from RF to an intermediate frequency (IF) in one stage, and then from IF to baseband in another stage for a receiver. In the direct-conversion architecture, a signal is frequency converted between RF and baseband in one stage. The super-heterodyne and direct-conversion architectures may use different circuit blocks and/or have different requirements. In the example shown in FIG. 2A, transmitter 230 and receiver 250 are implemented with the direct-conversion architecture.

In the transmit path, the data processor 210 processes data to be transmitted and provides in-phase (I) and quadrature (Q) analog output signals to the transmitter 230. In an exemplary embodiment, the data processor 210 includes digital-to-analog-converters (DAC's) 214a and 214b for converting digital signals generated by the data processor 210 into the I and Q analog output signals, e.g., I and Q output currents, for further processing. In other embodiments, the DACs 214a and 214b are included in the transceiver 220 and the data processor 210 provides data (e.g., for I and Q) to the transceiver 220 digitally.

Within the transmitter 230, lowpass filters 232a and 232b filter the I and Q analog transmit signals, respectively, to remove undesired images caused by the prior digital-to-analog conversion. Amplifiers (Amp) 234a and 234b amplify the signals from lowpass filters 232a and 232b, respectively, and provide I and Q baseband signals. An upconverter 240 having upconversion mixers 241a and 241b upconverts the I and Q baseband signals with I and Q transmit (TX) local oscillator (LO) signals from a TX LO signal generator 290 and provides an upconverted signal. A filter 242 filters the upconverted signal to remove undesired images caused by the frequency upconversion as well as noise in a receive frequency band. A power amplifier (PA) 244 amplifies the signal from filter 242 to obtain the desired output power level and provides a transmit RF signal. The transmit RF signal is routed through a duplexer or switch 246 and transmitted via an antenna 248, or alternatively it can be sent to a separate transmit antenna different from a separate receive antenna. While examples discussed herein utilize I and Q signals, those of skill in the art will understand that components of the transceiver may be configured to utilize polar modulation.

In the receive path, antenna 248 receives communication signals and provides a received RF signal, which can be routed through duplexer or switch 246 and provided to a low noise amplifier (LNA) 252. The duplexer 246 is designed to operate with a specific RX-to-TX duplexer frequency separation, such that RX signals are isolated from TX signals. Alternatively, there may be a separate transmit antenna and separate receive antenna as mentioned above, in which case RX-to-TX isolation can be achieved through the limited coupling between the two antennas. In the case of separate RX and TX antennas, the RX antenna can be coupled directly to LNA 252. The received RF signal is amplified by LNA 252 and filtered by a filter 254 to obtain a desired RF input signal. Downconversion mixers 261a and 261b in a downconverter 260 mix the output of filter 254 with I and Q receive (RX) LO signals (i.e., LO_I and LO_Q) from an RX LO signal generator 280 to generate I and Q baseband signals. The I and Q baseband signals are amplified by amplifiers 262a and 262b and further filtered by lowpass filters 264a and 264b to obtain I and Q analog input signals, which are provided to data processor 210. In the exemplary embodiment shown, the data processor 210 includes analog-to-digital-converters (ADC's) 216a and 216b for converting the analog input signals into digital signals to be further processed by the data processor 210. In some embodiments, the ADCs 216a and 216b are included in the transceiver 220 and provide data to the data processor 210 digitally.

In FIG. 2A, TX LO signal generator 290 generates the I and Q TX LO signals used for frequency upconversion, while RX LO signal generator 280 generates the I and Q RX LO signals used for frequency downconversion. Each LO signal is a periodic signal with a particular fundamental frequency. A phase locked loop (PLL) 292 receives timing information from data processor 210 and generates a control signal used to adjust the frequency and/or phase of the TX LO signals from LO signal generator 290. Similarly, a PLL 282 receives timing information from data processor 210 and generates a control signal used to adjust the frequency and/or phase of the RX LO signals from LO signal generator 280.

In an exemplary embodiment, the RX PLL 282, the TX PLL 292, the RX LO signal generator 280, and the TX LO signal generator 290 may alternatively be combined into a single LO generator circuit 295, which may include common or shared LO signal generator circuitry to provide the TX LO signals and the RX LO signals. Alternatively, separate LO generator circuits may be used to generate the TX LO signals and the RX LO signals.

Wireless device 200 may support CA and may (i) receive multiple downlink signals transmitted by one or more cells on multiple downlink carriers at different frequencies and/or (ii) transmit multiple uplink signals to one or more cells on multiple uplink carriers. Those of skill in the art will understand, however, that aspects described herein may be implemented in systems, devices, and/or architectures that do not support carrier aggregation.

Certain components of the transceiver 220 are functionally illustrated in FIG. 2A, and the configuration illustrated therein may or may not be representative of a physical device configuration in certain implementations. For example, as described above, transceiver 220 may be implemented in various integrated circuits (ICs), RF ICs (RFICs), mixed-signal ICs, etc. In some embodiments, the transceiver 220 is implemented on a substrate or board such as a printed circuit board (PCB) having various modules, chips, and/or components. For example, the power amplifier 244, the filter 242, and the duplexer 246 may be implemented in separate modules or as discrete components, while the remaining components illustrated in the transceiver 220 may be implemented in a single transceiver chip.

The power amplifier 244 may comprise one or more stages comprising, for example, driver stages, power amplifier stages, or other components, that can be configured to amplify a communication signal on one or more frequencies, in one or more frequency bands, and at one or more power levels. Depending on various factors, the power amplifier 244 can be configured to operate using one or more driver stages, one or more power amplifier stages, one or more impedance matching networks, and can be configured to provide good linearity, efficiency, or a combination of good linearity and efficiency.

In an exemplary embodiment in a super-heterodyne architecture, the filter 242, PA 244, LNA 252 and filter 254 may be implemented separately from other components in the transmitter 230 and receiver 250 (e.g., such a configuration may implement a millimeter wave integrated circuit (mmW-IC) or other super-heterodyne based architecture). An example super-heterodyne architecture is illustrated in FIG. 2B.

FIG. 2B is a block diagram showing a wireless device in which the exemplary techniques of the present disclosure may be implemented. Certain components, for example which may be indicated by identical reference numerals, of the wireless device 200a in FIG. 2B may be configured similarly to those in the wireless device 200 shown in FIG. 2A and the description of identically numbered items in FIG. 2B will not be repeated.

The wireless device 200a is an example of a heterodyne (or superheterodyne) architecture in which the upconverter 240 and the downconverter 260 are configured to process a communication signal between baseband and an intermediate frequency (IF). For example, the upconverter 240 may be configured to provide an IF signal to an upconverter 275. In an exemplary embodiment, the upconverter 275 may comprise upconversion mixer 276. The summing function 278 of upconverter 240 combines the I and the Q outputs and provides a combined signal to the mixer 276. The combined signal may be single ended or differential. The mixer 276 is configured to receive the IF signal from the upconverter 240 and TX RF LO signals from a TX RF LO signal generator 277, and provide an upconverted RF signal to phase shift circuitry 281. While PLL 292 is illustrated in FIG. 2B as being shared by the signal generators 290, 277, a respective PLL for each signal generator may be implemented.

In an exemplary embodiment, components in the phase shift circuitry 281 may comprise one or more adjustable or variable phased array elements, and may receive one or more control signals from the data processor 210 over connection 294 and operate the adjustable or variable phased array elements based on the received control signals.

In an exemplary embodiment, the phase shift circuitry 281 comprises phase shifters 283 and phased array elements 287. Although three phase shifters 283 and three phased array elements 287 are shown for ease of illustration, the phase shift circuitry 281 may comprise more or fewer phase shifters 283 and phased array elements 287.

Each phase shifter 283 may be configured to receive the RF transmit signal from the upconverter 275, alter the phase by an amount, and provide the RF signal to a respective phased array element 287. Each phased array element 287 may comprise transmit and receive circuitry including one or more filters, amplifiers, driver amplifiers, and power amplifiers. In some embodiments, the phase shifters 283 may be incorporated within respective phased array elements 287.

The output of the phase shift circuitry 281 is provided to an antenna array 248. In an exemplary embodiment, the antenna array 248 comprises a number of antennas that typically correspond to the number of phase shifters 283 and phased array elements 287, for example such that each antenna element is coupled to a respective phased array element 287. In an exemplary embodiment, the phase shift circuitry 281 and the antenna array 248 may be referred to as a phased array.

In a receive direction, a receive signal may be phase shifted and an output of the phase shift circuitry 281 is provided to a downconverter 285. In an exemplary embodiment, the downconverter 285 may comprise a downconversion mixer 286. In an exemplary embodiment, the mixer 286 downconverts the receive RF signal provided by the phase shift circuitry 281 to an IF signal according to RX RF LO signals provided by an RX RF LO signal generator 279. The I/Q generation function 291 of downconverter 260 receives the IF signal from the mixer 286 and generates I and Q signals in downconverter 260, which downconverts the IF signals to baseband, as described above. While PLL 282 is illustrated in FIG. 2B as being shared by the signal generators 280, 279, a respective PLL for each signal generator may be implemented.

In some embodiments, the upconverter 275, downconverter 285, and the phase shift circuitry 281 are implemented on a common IC. In some embodiments, the summing function 278 and the I/Q generation function 291 are implemented separate from the mixers 276 and 286 such that the mixers 276, 286 and the phase shift circuitry 281 are implemented on the common IC, but the summing function 278 and I/Q generation function 291 are not (e.g., the summing function 278 and I/Q generation function 291 are implemented in another IC coupled to the IC having the mixers 276, 286). In some embodiments, the LO signal generators 277, 279 are included in the common IC. In some embodiments in which phase shift circuitry is implemented on a common IC with 276, 286, 277, 278, 279, and/or 291, the common IC and the antenna array 248 are included in a module, which may be coupled to other components of the transceiver 220 via a connector. In some embodiments, the phase shift circuitry 281, for example, a chip on which the phase shift circuitry 281 is implemented, is coupled to the antenna array 248 by an interconnect. For example, components of the antenna array 248 may be implemented on a substrate and coupled to an integrated circuit implementing the phase shift circuitry 281 via a flexible printed circuit or the chip may be mounted on the substrate.

In some embodiments, both the architecture illustrated in FIG. 2A and the architecture illustrated in FIG. 2B are implemented in the same device. For example, a wireless device 110 or 200 may be configured to communicate with signals having a frequency below about 7 GHZ (e.g., the FRI frequency band) using the architecture illustrated in FIG. 2A and to communicate with signals having a frequency above about 24 GHz using the architecture illustrated in FIG. 2B. In devices in which both architectures are implemented, one or more components of FIGS. 2A and 2B that are identically numbered may be shared between the two architectures. For example, both signals that have been downconverted directly to baseband from RF and signals that have been downconverted from RF to baseband via an IF stage may be filtered by the same baseband filter 264. In other embodiments, a first version of the filter 264 is included in the portion of the device which implements the architecture of FIG. 2A and a second version of the filter 264 is included in the portion of the device which implements the architecture of FIG. 2B.

FIG. 2C is a block diagram showing a wireless device in which exemplary techniques of the present disclosure may be implemented. Certain components, for example which may be indicated by identical reference numerals, of the wireless device 200b in FIG. 2C may be configured similarly to those in the wireless device 200 shown in FIG. 2A and/or the wireless device 200a shown in FIG. 2B and the description of identically numbered items in FIG. 2C will not be repeated.

The wireless device 200b in FIG. 2C incorporates the phase shift circuitry 281 (of FIG. 2B) in a direct conversion architecture, where transmission signals are upconverted and downconverted between baseband and RF without the use of intermediate frequency (IF) signal conversion. Such an architecture may be referred to as a low IF (LIF), or a zero IF (ZIF) architecture. For example, the LO signals in the architecture of FIG. 2C may comprise signals at frequencies of tens of GHz or more.

In some embodiments, the upconverter 240, downconverter 260, and the phase shift circuitry 281 are implemented on a common IC. In some embodiments, the LO signal generators 280, 290 are included in the common IC. In some embodiments, the common IC and the antenna array 248 are included in a module, which may be coupled to other components of the transceiver 220 via a connector. In some embodiments, the phase shift circuitry 281, for example, a chip on which the phase shift circuitry 281 is implemented, is coupled to the antenna array 248 by an interconnect or both are mounted to a substrate. For example, components of the antenna array 248 may be implemented on a substrate and coupled to an integrated circuit implementing the phase shift circuitry 281 via a flexible printed circuit or the integrated circuit may be mounted to an opposite side of the substrate. In some embodiments, multiple iterations of the upconverter 240 and downconverter 260 may be implemented to process multiple signals on different frequency bands.

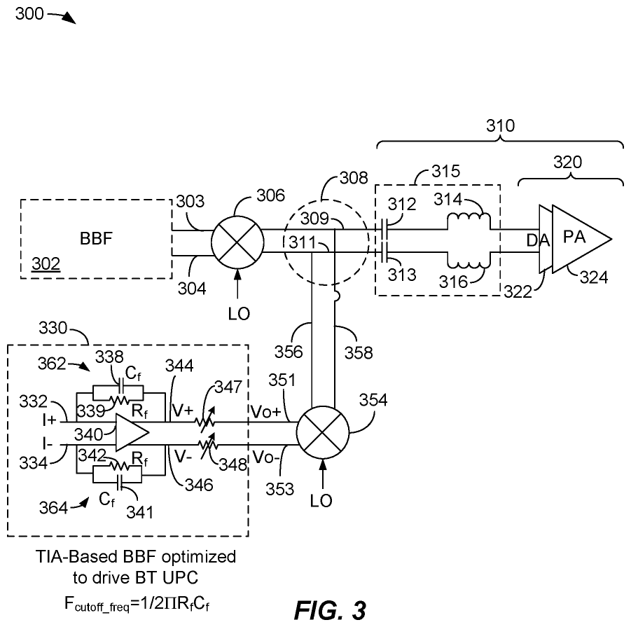

FIG. 3 is a diagram showing an upconverter circuit 300 in accordance with an exemplary embodiment. In an exemplary embodiment, the upconverter circuit 300 may be an example of the upconverter 240 of FIG. 2A or FIG. 2C. In an exemplary embodiment, the upconverter circuit 300 may be configured to operate on a wireless local area network (WLAN) communication signal and on a Bluetooth (BT) communication signal.

In an exemplary embodiment, a baseband filter (BBF) 302 may be coupled to a WLAN upconverter 306 over differential signal connections 303 and 304. In an exemplary embodiment, the WLAN upconverter 306 is a passive upconverter. The WLAN upconverter 306 may be configured to receive a local oscillator (LO) signal (for example, from the LO signal generator 290 of FIG. 2A or FIG. 2C), and may be configured to operate on signals at WLAN frequencies. The WLAN upconverter 306 may be connected to a load 310 over differential connections 309 and 311. However, a single-ended implementation is also possible. In an exemplary embodiment, the load 310 may comprise a matching network 315 and an amplifier circuit 320. The matching network 315 may comprise capacitances 312 and 313, and may comprise inductances 314 and 316. In other embodiments, the matching network 315 may comprise other circuit elements (e.g., some other impedance matching network circuit). In an exemplary embodiment, the amplifier circuit 320 may comprise one or more stages, with an exemplary driver stage 322 and power amplifier stage 324 shown for example.

In an exemplary embodiment, a baseband filter 330 may be coupled to a BT upconverter 354 over differential signal connections 351 and 353. In an exemplary embodiment, the BT upconverter 354 is a passive upconverter. The BT upconverter 354 may be configured to receive a local oscillator (LO) signal (for example, from the LO signal generator 290 of FIG. 2A or FIG. 2C), and may be configured to operate on signals at Bluetooth (BT) frequencies.

The baseband filter 330 may be implemented using a transimpedance amplifier (TIA)-based baseband filter having an operational transconductance amplifier (OTA) as will be described herein. The OTA may also be referred to as an operation amplifier (opamp). In an exemplary embodiment, the baseband filter 330 comprises an operational amplifier 340 configured to receive differential current input signals I+ and I− on differential signal connections 332 and 334, respectively, and to provide differential voltage output signals V+ and V− on differential signal connections 344 and 346, respectively. This arrangement is generally referred to as voltage mode.

In an exemplary embodiment, the output of the operational amplifier 340 on connections 344 and 346 is provided to attenuators 347 and 348, respectively. The output of the attenuators, Vo+ and Vo−, is provided over differential signal connections 351 and 353 to the BT upconverter 354.

In an exemplary embodiment, the baseband filter 330 also comprises a filter network 362 having a capacitance 338 and a resistance 339, and a filter network 364 having a capacitance 341 and a resistance 342.

In an exemplary embodiment, the values of the capacitances 338 (Cf) and 341 (Cf) and the values of the resistances 339 (Rf) and 342 (Rf) are chosen such that baseband filter 330 may have a cutoff frequency of F_{cutoff_freq}=½IIR_{f}C_{f}.

In an exemplary embodiment, the TIA-based baseband filter 330 may be optimized to drive the BT upconverter 354.

In an exemplary embodiment, because both the WLAN upconverter 306 and the BT upconverter 354 are passive upconverters, the output of the WLAN upconverter 306 and the output of the BT upconverter 354 may be coupled to an input of the matching network 315 without additional switching circuitry used in the area noted by reference numeral 308 (e.g., the outputs are simultaneously coupled to the load 310 during operation although the BT upconverter 354 and the WLAN upconverter 306 are not both simultaneously operating). In some aspects the output of the BT upconverter 354 is directly coupled to an input of the matching network 315 (e.g., no additional switching circuitry) and in some aspects the output of the WLAN upconverter 306 is directly coupled to an input of the matching network 315 (e.g., no additional switching circuitry).

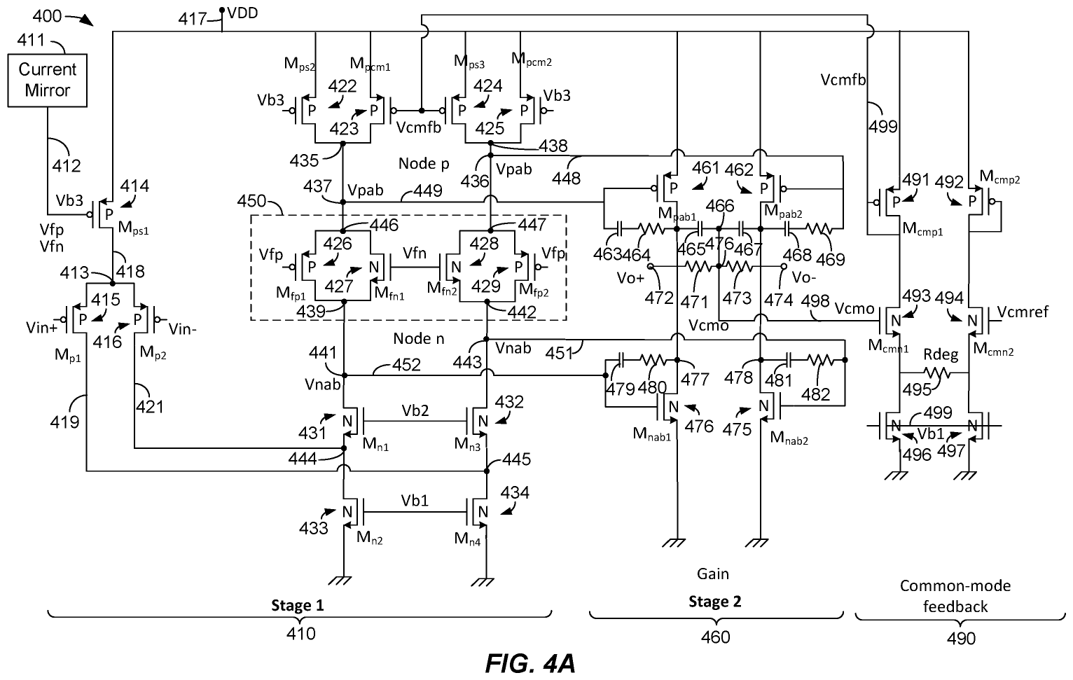

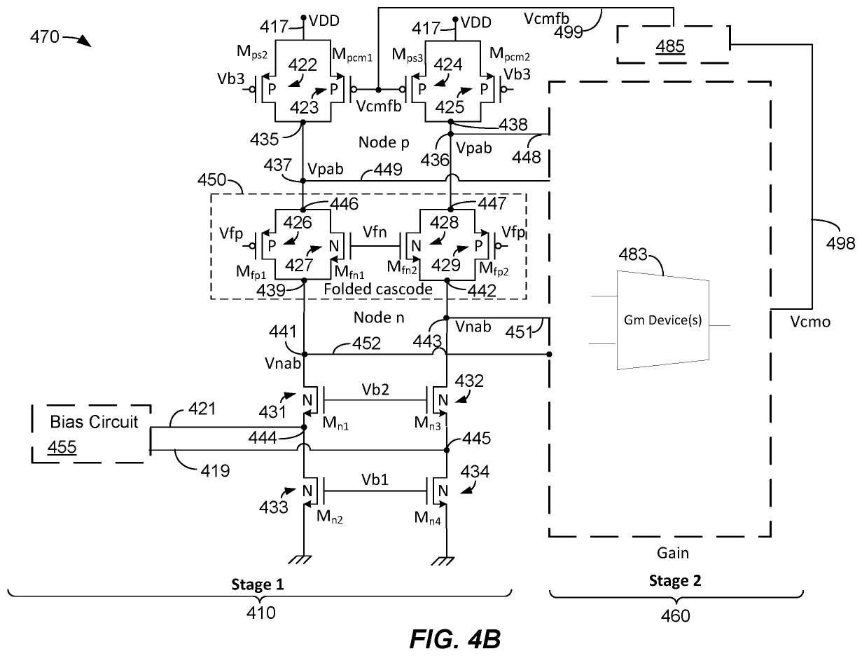

FIG. 4A is a diagram showing an operational transconductance amplifier (OTA) circuit 400 used in a baseband filter of FIG. 3. The circuit 400 will also be referred to as an operational amplifier (opamp). In an exemplary embodiment, the circuit 400 may be an example of the operational amplifier 340 of FIG. 3. In an exemplary embodiment, the circuit 400 comprises a first stage 410, a second stage 460 and a common-mode feedback circuit 490.

As used herein, the term connected generally refers to electrical connection that may or may not be a direct connection. For example, the term “connected” may refer to elements being electrically coupled and may include intervening circuit elements (capacitors or otherwise) while maintaining the described functionality of the circuit.

In an exemplary embodiment, the first stage 410 generally comprises a current mirror circuit 411 connected to a gate of transistor 414 over a connection 412. A source of the transistor 414 may be connected to a system voltage, VDD, over connection 417 and a drain of the transistor 414 may be connected to a node 413 over connection 418. The node 413 may be formed by connecting the source of a transistor 415 to a source of a transistor 416. A gate of the transistor 415 may be configured to receive a differential input signal, Vin+. A gate of the transistor 416 may be configured to receive a differential input signal, Vin−. The circuit 400 generally comprises a current to voltage amplifier and as such, the operational amplifier 340 in FIG. 3 is shown as having current inputs. These current inputs create input voltage at the gates of the transistors 415 and 416, so the inputs to the circuit 400 are shown as voltage inputs Vin+ and Vin− in FIG. 4A.

A drain of the transistor 415 may be connected to a node 445 and a drain of the transistor 416 may be connected to a node 444. The transistors 414, 415 and 416 may be P-type devices in an exemplary embodiment.

In an exemplary embodiment, the first stage 410 also comprises transistors 422, 423, 424 and 425. A source of each of the transistors 422, 423, 424 and 425 may be connected to the system voltage, VDD, over connection 417. A drain of the transistor 422 may be connected to a drain of the transistor 423 at a node 435. A drain of the transistor 424 may be connected to a drain of the transistor 425 at a node 438. A bias signal, Vb3, may be applied to a gate of the transistor 422 and to a gate of the transistor 425. A bias signal, Vcmfb (common-mode feedback voltage), may be applied to a gate of the transistor 423 and a gate of the transistor 424. In an exemplary embodiment, the transistors 422, 423, 424 and 425 may be P-type devices.

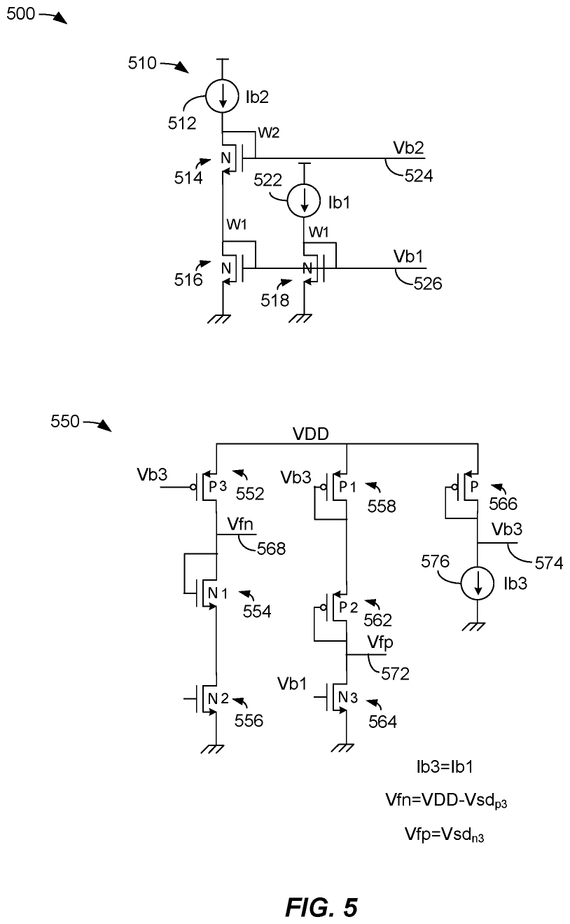

In an exemplary embodiment, the first stage 410 also comprises transistors 431, 432, 433 and 434. A source of the transistor 431 may be connected to a drain of the transistor 433; and a source of the transistor 432 may be connected to a drain of the transistor 434. A source of the transistor 433 may be connected to a system ground (or some other reference potential), and a source of the transistor 434 may be connected to a system ground, (or some other reference potential). In an exemplary embodiment, the transistors 431, 432, 433 and 434 may be referred to as tail transistor devices because they flow what may be referred to as a tail current. A bias signal, Vb1, may be applied to a gate of the transistor 433 and a gate of the transistor 434. A bias signal, Vb2, may be applied to a gate of the transistor 431 and a gate of the transistor 432. The circuitry that generates the bias signals Vb1, Vb2 and Vb3 is shown and described in greater detail in FIG. 5 (and such bias circuitry is represented in part by the current mirror 411).

A drain of the transistor 431 may be connected to a node 441 and a drain of the transistor 432 may be connected to a node 443. In an exemplary embodiment, the transistors 431, 432, 433 and 434 may be N-type devices.

In an exemplary embodiment, the transistors 415 and 416 are considered folded, and the transistors 422, 423, 424 and 425, and the transistors 431, 432, 433 and 434 form a cascode architecture, where the transistors 415 and 416, and the transistors 422, 423, 424 and 425, and the transistors 431, 432, 433 and 434 are considered a folded cascode structure.

In an exemplary embodiment, PMOS-NMOS transistor pairs (PMOS-NMOS pairs) 450 may be formed by transistors 426, 427, 428 and 429. A source of the transistor 426 may be connected to a drain of the transistor 427 at a node 446; and a drain of the transistor 426 may be connected to a source of the transistor 427 at a node 439. A source of the transistor 429 may be connected to a drain of the transistor 428 at a node 447; and a drain of the transistor 429 may be connected to a source of the transistor 428 at a node 442.

The node 446 may be connected to the node 437, which may be connected to the node 435. The node 447 may be connected to the node 436, which may be connected to the node 438. The node 439 may be connected to the node 441 and the node 442 may be connected to the node 443. In an exemplary embodiment, the node 437 and the node 436 may be referred to as “node p” having a voltage Vpab; and the node 441 and the node 443 may be referred to as “node n” having a voltage Vnab. In an exemplary embodiment, the transistors 426 and 429 may be P-type devices and the transistors 427 and 428 may be N-type devices. A bias signal Vfp may be applied to the gate of the transistor 426 and the gate of the transistor 429; and a bias signal Vfn may be applied to the gate of the transistor 427 and the gate of the transistor 428. The circuitry that generates the bias signals Vfp and Vfn will be described in FIG. 5.

In an exemplary embodiment, the second stage 460 comprises transistors 461, 462, 475 and 476. A source of the transistor 461 and a source of the transistor 462 may be connected to the system voltage, VDD, over connection 417. A drain of the transistor 461 may be connected to a drain of the transistor 476, and a drain of the transistor 462 may be connected to a drain of the transistor 475. A gate of the transistor 461 may be connected to the drain of the transistor 461 through a capacitance 463 and a resistance 464. A gate of the transistor 462 may be connected to the drain of the transistor 462 through a capacitance 468 and a resistance 469. The drain of the transistor 461 may also be connected to a node 466 through a capacitance 465, and the drain of the transistor 462 may also be connected to the node 466 through a capacitance 467. The node 466 may be connected to a node 476. A differential output signal, Vo+, may be taken from the node 472 through a resistance 471 and a differential output signal, Vo−, may be taken from the node 474 through a resistance 473. The node 472 in FIG. 4A may correspond to the connection 351 in FIG. 3 and the node 474 in FIG. 4A may correspond to the connection 353 in FIG. 3. In an exemplary embodiment, the transistors 461 and 462 are P-type devices.

A drain of the transistor 476 may be connected to a gate of the transistor 476 through a resistance 480 and a capacitance 479. A drain of the transistor 475 may be connected to a gate of the transistor 475 through a resistance 482 and a capacitance 481. In an exemplary embodiment, the transistors 475 and 476 are N-type devices.

A bias signal, Vpab, may be applied to the gate of the transistor 461 from the node 437 over connection 449, and may be applied to the gate of the transistor 462 from the node 436 over connection 448.

A bias signal, Vnab, may be applied to the gate of the transistor 476 from the node 441 over connection 452, and may be applied to the gate of the transistor 475 from the node 443 over connection 451.

In an exemplary embodiment, the common-mode feedback circuit 490 comprises transistors 491, 492, 493, 494, 496 and 497. A source of the transistor 491 and a source of the transistor 492 are connected to the system voltage, VDD, over connection 417. A drain of the transistor 491 may be connected to a drain of the transistor 493, and a drain of the transistor 492 may be connected to a drain of the transistor 494. A source of the transistor 493 may be connected to a drain of the transistor 496 and a source of the transistor 494 may be connected to a drain of the transistor 497.

In an exemplary embodiment, the drain and gate of the transistor 491 are connected together, and the drain and gate of the transistor 492 are connected together. A bias signal, Vcmfb (common-mode feedback), is applied to the gate of the transistor 491 over connection 499.

A common mode output signal, Vcmo (common mode voltage), is applied to the gate of the transistor 493 from the node 476 over connection 498. A common mode reference signal, Vcmref, is applied to the gate of the transistor 494. The bias signal, Vb1, is applied to the gate of the transistor 496 and the gate of the transistor 497 at a connection 499. In an exemplary embodiment, the transistors 491 and 492 may be P-type devices and the transistors 493, 494, 496 and 497 may be N-type devices.

In an exemplary embodiment, the transistors 426, 427, 428 and 429 in the PMOS-NMOS pairs 450 have a channel length that is longer than a channel length of the other transistors in the first stage 410. For example, the impedance looking at the transistors 426, 427, 428 and 429 connected to nodes 437/436 (Vpab) and nodes 441/443 (Vnab) remains sufficiently high, while maintaining the transistors 431 (Mn1) and 433 (Mn2) and the transistors 432 (Mn3) and 434 (Mn4) in the saturation region, to provide sufficient gain from the first stage 410. The bias of the transistors 431/432 (Mn1/Mn3) and the transistors 433/434 (Mn2/Mn4) are configured such that the voltage at nodes 441/443 (Vnab), which is gate voltage of the second stage NMOS transistors 475 and 476, is low enough to maintain low current consumption in the NMOS devices (transistors 475 and 476) in the second stage 460, but also keeps the transistors 431 (Mn1) and 433 (Mn2) and the transistors 432 (Mn3) and 434 (Mn4) in the saturation region. For example, it is desirable to keep current in the second stage 460 low to reduce power consumption. However, the voltage at the nodes 441 and 443 (Vnab) is also the gate voltage of the second stage transistors 475 and 476, so increasing Vnab increases second stage current. In some circumstances, Vnab can increase too high. Therefore, the size of the transistors 431 and 433 (and 432 and 434) should be relatively large so that the voltage Vnab does not get too high and increase the current through the second stage 460.

In an exemplary embodiment, the transistors 426/427 (Mfp1/Mfn1) and the transistors 428/429 (Mfn2/Mfp2) act as push-pull PMOS-NMOS pairs while in class AB operation, without using any AC coupling capacitors between the first stage 410 and the second stage 460. The term push-pull refers to the arrangement where one transistor is sourcing current to a load and the other transistor is sinking current to a load. In this manner, high linearity, and good gain resolution are not tied to power consumption in the circuit 400 and are not compromised by AC coupling capacitances. The circuit arrangement shown in FIG. 4A provides high linearity and low power consumption. In an exemplary embodiment, the circuit 400 may be fabricated using a low area, 22 nm process, which may produce a TIA having a lower circuit area than a current-mode amplifier in a baseband filter.

The PMOS-NMOs pairs 450 in the first stage 410 has PMOS-NMOS pairs 426/427 (Mfn1/Mfp1) and PMOS-NMOS pairs 428/429 (Mfn2/Mfp2) between NMOS stages (transistors 431, 432, 433 and 434) and PMOS stages (cascode transistors 422, 423, 424 and 425) to bias the NMOS and PMOS transistors (transistors 461/462 and 476/475) in the second stage 460 in class AB mode. The channel length of the PMOS-NMOS transistor pairs (426/427 and 428/429) is sufficiently long such that the impedance looking towards nodes 441 and 443 (node n (Vnab)) and nodes 437 and 436 (node p (Vpab)) remains high so that the gain of the first stage 410 does not degrade significantly. The bias of the transistor 431 (Mn1) and 432 (Mn3) and 433 (Mn2) and 434 (Mn4) is such that Vnab should be limited to maintain low power consumption in the second stage 460 but still keep the transistor 431 (Mn1) and the transistor 433 (Mn2) in the saturation region, as described above

In an exemplary embodiment, the current consumption of the circuit 400 remains below 4 mA from a 1.2V supply in order to be comparable with a traditional current mode baseband filter. The bias voltages Vfp and Vfn can be generated from the same current mirror source as Vb3. Therefore, the bias voltages Vfp and Vfn of the PMOS-NMOS pair (426/427 and 428/429), should be such that:

Vfn≥V_{b1}−V_{th-Mn2}+V_{dssat-Mn1}+V_{gs-Mfn1}; and

Vfp≤V_{sdsat-Mp1}−V_{sg-Mfp1}.

The term V_{b1} refers to the gate voltage of the transistors 433 and 434; the term V_{th-Mn2} refers to the gate voltage of the transistor 433; the term V_{dssat-Mn1} refers to the drain-source saturation voltage of the transistor 431; the term V_{gs-Mfn1} refers to the gate-source voltage of the transistors 427 and 428; the term V_{sdsat-Mp1} refers to the source-drain saturation voltage of the transistor 415; and the term V_{sg-Mfp1} refers to the source-gate voltage of the transistors 426 and 429.

Another challenge in the architecture is to stabilize the common-mode feedback loop. The common-mode feedback circuit 490 attempts to regulate the output DC bias voltage which is the voltage that Vcmref sets. The voltage, Vcmref, is provided by a reference voltage generator (not shown). In an exemplary embodiment, the reference voltage, Vcmref, may be approximately VDD/2. The common-mode feedback circuit 490 may also be referred to as an error amplifier and sets the voltage Vcmfb, which controls the voltage at node p (Vpab, nodes 437 and 436). The common-mode feedback circuit 490 is designed in such a way that Vpab and Vnab provide sufficient headroom to keep all transistors in the first stage 410 in saturation. The degeneration resistor 495 (Rdeg) improves the stability of the common-mode loop but degrades the gain of the common-mode feedback circuit 490. In an exemplary embodiment, the common-mode feedback circuit 490 compares the voltage, Vcmo at node 476 with the reference voltage, Vcmref, and then adjusts the voltage, Vcmfb, accordingly. In an exemplary embodiment, the gain of the circuit 400 should remain approximately 30 dB to reduce the variation in Vcmo over temperature and process variation while keeping the amplifier phase margin at or near 45 degrees.

For example, if a disturbance such as a change in supply voltage, variation in signal input strength, etc., causes the voltage Vcmo (which is Vo++Vo−) to increase, the current through the transistor 493 decreases, which in turn causes the voltage Vcmfb, to decrease. This causes the voltage at node 437 and node 436 to increase (because the gate and drain of the transistors 422, 432, 424 and 425 are in opposite phase), which means the gate source voltage, Vgs, of the PMOS transistors 461, 462 in the second stage 460 gets lowered, and the output voltages at node 472 and node 474 are decreased. Thus, any change in the output voltage, Vo+ and Vo−, is adjusted by the common mode feedback loop. In this manner, any change in the output voltages Vo+ and Vo−, causes the common mode feedback circuit 490 to adjust the common mode feedback voltage Vcmfb in such a way that the values of Vo+ and Vo− are returned to their original value which is close to Vdd/2. Thus, the DC voltage at node 472 and node 474 remains fixed by the common-mode feedback circuit 490.

The TIA-based filter and passive UPC architecture shows comparable linearity and gain resolution compared to a current-based RC filter and active UPC. In one example, the gain resolution can be achieved by implementing the attenuators 347 and 348 (FIG. 3) as 8-bit attenuators, where the baseband filter 330 (FIG. 3) can provide approximately 60 dB gain, which is sufficient for GFSK/EDR applications. Whether the transmitter is in WLAN mode or BT mode, the unused UPC is turned OFF, resulting in no need for any switches. Only off-state parasitics of the off-UPC are considered in designing the load circuitry (matching network 315, FIG. 3). The architecture allows WLAN and BT transmitter applications where the UPC load is combined to reduce area and also allows the use of a common amplifier.

FIG. 4B is a diagram showing an alternative exemplary embodiment of the operational amplifier (OTA) circuit of FIG. 4A. In FIG. 4B, the circuit 470 is similar to the circuit 400. In the circuit 470, the current mirror 411, transistor 414, transistor 415, the transistor 416, and portions of the bias circuit 510 (FIG. 5) are generalized into the bias circuit 455. The second stage 460 is represented by one or more gain (Gm) devices 483, and the common-mode feedback circuit 490 is represented by common-mode feedback circuit 485. In an exemplary embodiment, the first stage 410 includes N-type and P-type transistor pair including transistors 427 and 426, and N-type and P-type transistor pair including transistors 428 and 429 that provide bias signals Vpab over connections 448 and 449, and provide bias signals Vnab over connections 451 and 452 to the second stage 460.

FIG. 5 is a diagram showing some of the bias voltages used in FIG. 4A and FIG. 4B. The bias circuit 510 may be used to generate the bias voltages Vb1 and Vb2 in FIG. 4A and FIG. 4B. The bias circuit 510 includes current source 512, transistors 514 and 516, current source 522 and transistor 518. In an exemplary embodiment, the transistors 514, 516, and 518 may be N-type transistors.

The current source 512 (Ib2) is connected to a drain of the transistor 514. The source of the transistor 514 is connected to the drain of the transistor 516 and the source of the transistor 516 is connected to ground.

The current source 522 (Ib1) is connected to a drain of the transistor 518. The source of the transistor 518 is connected to ground.

The gate and drain of the transistors 514, 516 and 518 are connected together. The gate of the transistors 516 and 518 provide the bias voltage Vb1 on connection 526. The gate of the transistor 514 provides the bias voltage Vb2 on connection 524. The bias voltage Vb1 is applied to the gates of the transistors 433 and 434 (FIG. 4A and FIG. 4B) and the bias voltage Vb2 is applied to the gates of the transistors 431 and 432 (FIG. 4A and FIG. 4B).

In an exemplary embodiment, the width (channel length) of the transistors 514, 516 and 518 are ratioed properly with respect to the transistors 431 and 433 (FIG. 4A and FIG. 4B) to obtain the desired bias current. For example, the width of the transistors 516 and 518 may be W1, the width of the transistor 514 may be W2, and the width of the transistors 431 and 433 (FIG. 4A and FIG. 4B) may be mW2 and nW1, respectively.

In an exemplary embodiment, the bias circuit 550 may be used to generate the bias voltages Vfn, Vfp and Vb3 in FIG. 4A and FIG. 4B. The bias circuit 550 includes transistors 552, 554, 556, 558, 562, 564, 566, and a current source 576. The transistors 552, 558, 566 and 562 may be P-type transistors and the transistors 554, 556 and 564 may be P-type transistors.

In an exemplary embodiment, the sources of the transistors 552, 558 and 566 are connected to system voltage, VDD. The drain of the transistor 552 is connected to the drain of the transistor 554. The source of the transistor 554 is connected to the drain of the transistor 556. The source of the transistor 556 is connected to ground. The drain and gate of the transistor 554 are connected together.

The drain of the transistor 558 is connected to the source of the transistor 562. The drain of the transistor 562 is connected to the drain of the transistor 564. The source of the transistor 564 is connected to ground. The drain and gate of the transistor 562 are connected together.

The drain of the transistor 566 is connected to the current source 576 (Ib3).

The bias voltage Vfn appears at the connection 568 between the drain of the transistor 552 and the drain of the transistor 554. The bias voltage Vfp appears at the connection 572 between the drain of the transistor 562 and the drain of the transistor 564. The bias voltage Vb3 appears at the connection 574 at the drain of the transistor 566. The bias voltage Vfn is applied to the gates of the transistors 427 and 428. The bias voltage Vfp is applied to the gates of the transistors 426 and 429. The bias voltage Vb3 is applied to the gate of the transistor 414 and to the gates of the transistors 422 and 425.

In an exemplary embodiment, the currents through the three circuit branches (552/554/556; 558/562/564; and 566/576) are set by sizing the transistors that satisfies Vfn and Vfp as follows.

V_{fn}≥V_{b1}−V_{th-Mn2}+V_{dssat-Mn1}+V_{gs-Mfn1}

V_{fp}≤V_{sdsat-Mp1}−V_{sg-Mfp1}

The transistors 554, 556, 558 and 562 are configured as diode connected loads and are acting as active resistors. Therefore, the voltage of Vfn and Vfp can be set by proper sizing of the current source transistors 552 (P3) and 564 (N3) and the diode connected transistors 554 (N1) and 556 (N2); and 558 (P1) and 562 (P2).

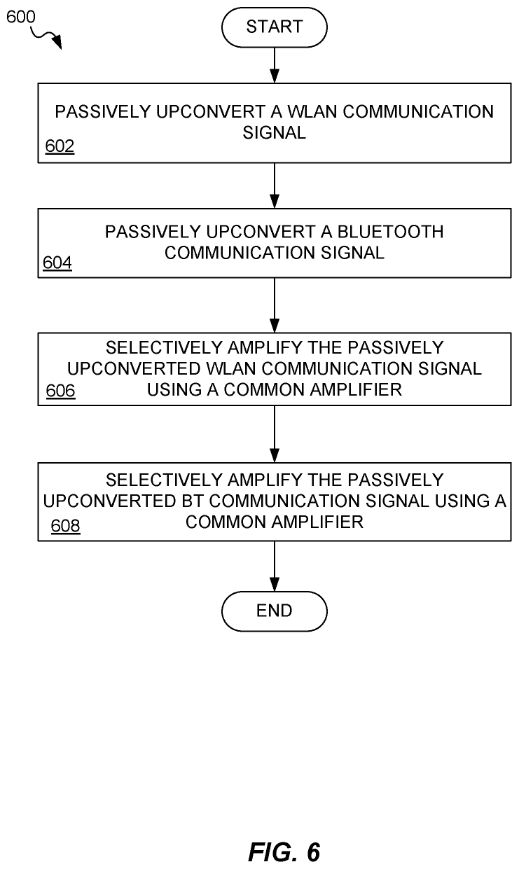

FIG. 6 is a flow chart 600 describing an example of the operation of a method for signal upconversion. The blocks in the method 600 can be performed in or out of the order shown, and in some embodiments, can be performed at least in part in parallel.

In block 602, a WLAN communication signal is passively upconverted. For example, the WLAN upconverter 306 can passively upconvert a WLAN communication signal provided by the baseband filter 302.

In block 604, a BT communication signal is passively upconverted. For example, the BT upconverter 354 can passively upconvert a BT communication signal provided by the baseband filter 330.

In block 606, the passively upconverted WLAN communication signal is selectively amplified using a common amplifier. For example, the amplifier 320 may amplify the WLAN communication signal provided by the WLAN upconverter 306.

In block 608, the passively upconverted BT communication signal is selectively amplified using a common amplifier. For example, the amplifier 320 may amplify a BT communication signal provided by the BT upconverter 354.

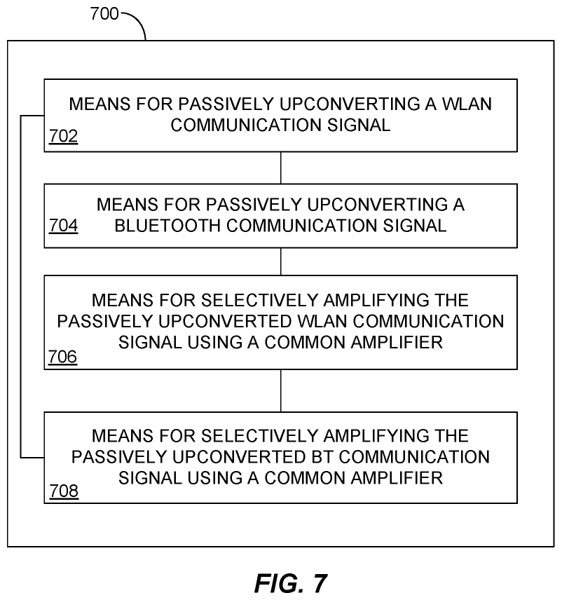

FIG. 7 is a functional block diagram of an apparatus 700 for signal upconversion. The apparatus 700 comprises means 702 for passively upconverting a WLAN communication signal. In certain embodiments, the means 702 for passively upconverting a WLAN communication signal can be configured to perform one or more of the functions described in operation block 602 of method 600 (FIG. 6). In an exemplary embodiment, the means 702 for passively upconverting a WLAN communication signal may comprise the WLAN upconverter 306 passively upconverting a WLAN communication signal provided by the baseband filter 302.

The apparatus 700 may also comprise means 704 for passively upconverting a BT communication signal. In certain embodiments, the means 704 for passively upconverting a BT communication signal can be configured to perform one or more of the functions described in operation block 604 of method 600 (FIG. 6). In an exemplary embodiment, the means 704 for passively upconverting a BT communication signal may comprise the BT upconverter 354 passively upconverting a BT communication signal provided by the baseband filter 330.

The apparatus 700 may also comprise means 706 for selectively amplifying the passively upconverted WLAN communication signal. In certain embodiments, the means 706 for selectively amplifying the passively upconverted WLAN communication signal can be configured to perform one or more of the functions described in operation block 606 of method 600 (FIG. 6). In an exemplary embodiment, the means 706 for selectively amplifying the passively upconverted WLAN communication signal may comprise the amplifier 320 amplifying a WLAN communication signal provided by the WLAN upconverter 306.

The apparatus 700 may also comprise means 708 for selectively amplifying the passively upconverted BT communication signal. In certain embodiments, the means 708 for selectively amplifying the passively upconverted BT communication signal can be configured to perform one or more of the functions described in operation block 608 of method 600 (FIG. 6). In an exemplary embodiment, the means 708 for selectively amplifying the passively upconverted BT communication signal may comprise the amplifier 320 amplifying a BT communication signal provided by the BT upconverter 354.

Implementation examples are described in the following numbered clauses:
1. A transimpedance-based baseband filter (BBF), comprising a two-stage operational transconductance amplifier (OTA) having a first stage based on a folded cascode topology, the first stage electrically coupled to a second stage, the second stage having a class AB topology, the first stage having an N-type and P-type transistor pair located between a P-type transistor and an N-type transistor, the N-type and P-type transistor pair configured to provide bias signals to push-pull transistors in the second stage.
2. The baseband filter of clause 1, wherein the N-type and P-type transistor pair further comprises a first pair of transistors having a P-type transistor device and an N-type transistor device; a second pair of transistors having a P-type transistor device and an N-type transistor device; and the first pair of transistors and the second pair of transistors located between respective P-type cascode transistors and N-type tail transistor devices in the first stage.
3. The baseband filter of clause 2, wherein the first pair of transistors and the second pair of transistors in the N-type and P-type transistor pair comprise respective channel lengths that are longer than channel lengths of the P-type cascode transistors and the N-type tail transistor devices in the first stage.
4. The baseband filter of clause 3, wherein the N-type and P-type transistor pair comprises an N-type node (Vnab) and a P-type node (Vpab) configured to provide the bias signals to the push-pull transistors in the second stage according to class AB operation.
5. The baseband filter of clause 4, wherein the push-pull transistors in the second stage comprise two pairs of N-type and P-type transistors.
6. The baseband filter of any of clauses 1 through 5, further comprising a common-mode feedback circuit configured to compare a common-mode voltage output of the second stage against a reference voltage and adjust a common-mode feedback voltage to the first stage in response to the common-mode voltage output of the second stage.
7. The baseband filter of clause 6, wherein the common-mode feedback voltage provided to the first stage is configured to adjust a bias voltage to the push-pull transistors in the second stage to adjust the DC bias voltage output of the second stage.
8. The baseband filter of any of clauses 1 through 7, wherein the baseband filter is coupled to an upconverter circuit comprising a passive Bluetooth upconverter coupled to an output of the second stage; a matching network coupled to the passive Bluetooth upconverter; a passive wireless local area network (WLAN) upconverter coupled to the matching network; a power amplifier coupled to the matching network, wherein the passive Bluetooth upconverter and the passive WLAN upconverter share the matching network and the power amplifier.
9. A method for signal conversion, comprising passively upconverting a wireless local area network (WLAN) communication signal; passively upconverting a Bluetooth (BT) communication signal; selectively amplifying the passively upconverted WLAN communication signal using a common amplifier; and selectively amplifying the passively upconverted BT communication signal using the common amplifier.
10. The method of clause 9, wherein passively upconverting the BT communication signal further comprises filtering the BT communication signal with a transimpedance amplifier (TIA)-based baseband filter operating in voltage mode.
11. The method of clause 10, wherein the TIA-based baseband filter comprises an operational amplifier having a first stage and a second stage, the first stage having PMOS-NMOS transistor pairs, wherein filtering the BT communication signal with the TIA-based baseband filter comprises providing bias signals to push-pull transistors via the PMOS-NMOS transistor pairs in the second stage according to class AB operation.
12. The method of clause 11, further comprising comparing a common-mode voltage output of the second stage against a reference voltage; and providing a common-mode feedback voltage to the first stage in response to the common-mode voltage output of the second stage.
13. The method of clause 12, further comprising adjusting a bias voltage to the push-pull transistors in the second stage to adjust an output of the second stage.
14. A device, comprising means for passively upconverting a wireless local area network (WLAN) communication signal; means for passively upconverting a Bluetooth (BT) communication signal; means for selectively amplifying the passively upconverted WLAN communication signal; and means for selectively amplifying the passively upconverted BT communication signal.
15. The device of clause 14, wherein the means for amplifying the passively upconverted WLAN communication signal and the means for amplifying the passively upconverted BT communication signal further comprises means for filtering the BT communication signal with a transimpedance amplifier (TIA)-based baseband filter operating in voltage mode.
16. The device of clause 15, wherein the TIA-based baseband filter comprises an operational amplifier having first stage means and second stage means, the first stage means having PMOS-NMOS transistor pairs for providing bias signals to push-pull transistors in the second stage means according to class AB operation.
17. The device of clause 16, further comprising means for comparing a common-mode voltage output of the second stage means against a reference voltage; and providing a common-mode feedback voltage to the first stage means in response to the common-mode voltage output of the second stage means.
18. The device of clause 17, further comprising means for adjusting a bias voltage to the push-pull transistors in the second stage means to adjust an output of the second stage means.
19. A transmit circuit, comprising Bluetooth (BT) communication circuitry comprising a passive BT upconverter (BT UPC) coupled to a load; wireless local area network (WLAN) communication circuitry comprising a passive WLAN upconverter (WLAN UPC) coupled to the load; and a voltage-mode baseband filter (BBF) having an operational transconductance amplifier (OTA) configured to provide a voltage input signal to the BT UPC.
20. The transmit circuit of clause 19, wherein the OTA comprises PMOS-NMOS transistor pairs located between P-type transistors and N-type transistors.
21. The transmit circuit of clause 20, wherein the PMOS-NMOS transistor pairs further comprise a first pair of transistors having a P-type transistor device and an N-type transistor device; a second pair of transistors having a P-type transistor device and an N-type transistor device; and the first pair of transistors and the second pair of transistors located between P-type cascode transistor devices and N-type tail transistor devices in a first stage of the OTA.
22. The transmit circuit of clause 21, wherein the first pair of transistors and the second pair of transistors in the PMOS-NMOS transistor pairs comprise respective channel lengths that are longer than channel lengths of the P-type cascode transistor devices and the N-type tail transistor devices in the first stage.
23. The transmit circuit of clause 22, wherein the PMOS-NMOS transistor pairs comprise an N-type node (Vnab) and a P-type node (Vpab) configured to provide bias signals to push-pull transistors in a second stage of the OTA in class AB operation.
24. The transmit circuit of clause 23, wherein the push-pull transistors in the second stage comprise two pairs of N-type and P-type transistors.
25. The transmit circuit of any of clauses 19 through 24, wherein the voltage-mode BBF further comprises a common-mode feedback circuit configured to compare a common-mode voltage output of a second stage against a reference voltage and adjust a common-mode feedback voltage to a first stage in response to the common-mode voltage output of the second stage.
26. The transmit circuit of clause 25, wherein the common-mode feedback voltage provided to the first stage adjusts a bias voltage to push-pull transistors in the second stage to adjust the DC bias voltage output of the second stage.

The circuit architecture described herein described herein may be implemented on one or more ICs, analog ICs, RFICs, mixed-signal ICs, ASICs, printed circuit boards (PCBs), electronic devices, etc. The circuit architecture described herein may also be fabricated with various IC process technologies such as complementary metal oxide semiconductor (CMOS), N-channel MOS (NMOS), P-channel MOS (PMOS), bipolar junction transistor (BJT), bipolar-CMOS (BiCMOS), silicon germanium (SiGe), gallium arsenide (GaAs), heterojunction bipolar transistors (HBTs), high electron mobility transistors (HEMTs), silicon-on-insulator (SOI), etc.

An apparatus implementing the circuit described herein may be a stand-alone device or may be part of a larger device. A device may be (i) a stand-alone IC, (ii) a set of one or more ICs that may include memory ICs for storing data and/or instructions, (iii) an RFIC such as an RF receiver (RFR) or an RF transmitter/receiver (RTR), (iv) an ASIC such as a mobile station modem (MSM), (v) a module that may be embedded within other devices, (vi) a receiver, cellular phone, wireless device, handset, or mobile unit, (vii) etc.

Although selected aspects have been illustrated and described in detail, it will be understood that various substitutions and alterations may be made therein without departing from the spirit and scope of the present invention, as defined by the following claims.

What is claimed is:

1. A transimpedance-based baseband filter (BBF), comprising:
a two-stage operational transconductance amplifier (OTA) having a first stage based on a folded cascode topology, the first stage electrically coupled to a second stage, the second stage having a class AB topology, the first stage having an N-type and P-type transistor pair located between a P-type transistor and an N-type transistor, the N-type and P-type transistor pair configured to provide bias signals to push-pull transistors in the second stage.

2. The baseband filter of claim 1, wherein the N-type and P-type transistor pair further comprises:
a first pair of transistors having a P-type transistor device and an N-type transistor device;
a second pair of transistors having a P-type transistor device and an N-type transistor device; and
the first pair of transistors and the second pair of transistors located between respective P-type cascode transistors and N-type tail transistor devices in the first stage.

3. The baseband filter of claim 2, wherein the first pair of transistors and the second pair of transistors in the N-type and P-type transistor pair comprise respective channel lengths that are longer than channel lengths of the P-type cascode transistors and the N-type tail transistor devices in the first stage.

4. The baseband filter of claim 3, wherein the N-type and P-type transistor pair comprises an N-type node (Vnab) and a P-type node (Vpab) configured to provide the bias signals to the push-pull transistors in the second stage according to class AB operation.

5. The baseband filter of claim 4, wherein the push-pull transistors in the second stage comprise two pairs of N-type and P-type transistors.

6. The baseband filter of claim 1, further comprising:
a common-mode feedback circuit configured to compare a common-mode voltage output of the second stage against a reference voltage and adjust a common-mode feedback voltage to the first stage in response to the common-mode voltage output of the second stage.

7. The baseband filter of claim 6, wherein the common-mode feedback voltage provided to the first stage is configured to adjust a bias voltage to the push-pull transistors in the second stage to adjust a DC bias voltage output of the second stage.

8. The baseband filter of claim 1, wherein the baseband filter is coupled to an upconverter circuit comprising:
a passive Bluetooth upconverter coupled to an output of the second stage;
a matching network coupled to the passive Bluetooth upconverter;
a passive wireless local area network (WLAN) upconverter coupled to the matching network;
a power amplifier coupled to the matching network, wherein the passive Bluetooth upconverter and the passive WLAN upconverter share the matching network and the power amplifier.

9. A method for signal conversion, comprising:
passively upconverting a wireless local area network (WLAN) communication signal;
passively upconverting a Bluetooth (BT) communication signal;
selectively amplifying the passively upconverted WLAN communication signal using a common amplifier; and
selectively amplifying the passively upconverted BT communication signal using the common amplifier.

10. The method of claim 9, wherein passively upconverting the BT communication signal further comprises:
filtering the BT communication signal with a transimpedance amplifier (TIA)-based baseband filter operating in voltage mode.

11. The method of claim 10, wherein the TIA-based baseband filter comprises an operational amplifier having a first stage and a second stage, the first stage having PMOS-NMOS transistor pairs, wherein filtering the BT communication signal with the TIA-based baseband filter comprises providing bias signals to push-pull transistors via the PMOS-NMOS transistor pairs in the second stage according to class AB operation.

12. The method of claim 11, further comprising:
comparing a common-mode voltage output of the second stage against a reference voltage; and
providing a common-mode feedback voltage to the first stage in response to the common-mode voltage output of the second stage.

13. The method of claim 12, further comprising adjusting a bias voltage to the push-pull transistors in the second stage to adjust an output of the second stage.

14. A device, comprising:
means for passively upconverting a wireless local area network (WLAN) communication signal;
means for passively upconverting a Bluetooth (BT) communication signal;
means for selectively amplifying the passively upconverted WLAN communication signal; and
means for selectively amplifying the passively upconverted BT communication signal.

15. The device of claim 14, wherein the means for amplifying the passively upconverted WLAN communication signal and the means for amplifying the passively upconverted BT communication signal further comprises means for filtering the BT communication signal with a transimpedance amplifier (TIA)-based baseband filter operating in voltage mode.

16. The device of claim 15, wherein the TIA-based baseband filter comprises an operational amplifier having first stage means and second stage means, the first stage means having PMOS-NMOS transistor pairs for providing bias signals to push-pull transistors in the second stage means according to class AB operation.

17. The device of claim 16, further comprising:
means for comparing a common-mode voltage output of the second stage means against a reference voltage; and
providing a common-mode feedback voltage to the first stage means in response to the common-mode voltage output of the second stage means.

18. The device of claim 17, further comprising means for adjusting a bias voltage to the push-pull transistors in the second stage means to adjust an output of the second stage means.

19. A transmit circuit, comprising:
Bluetooth (BT) communication circuitry comprising a passive BT upconverter (BT UPC) coupled to a load;
wireless local area network (WLAN) communication circuitry comprising a passive WLAN upconverter (WLAN UPC) coupled to the load; and
a voltage-mode baseband filter (BBF) having an operational transconductance amplifier (OTA) configured to provide a voltage input signal to the BT UPC.

20. The transmit circuit of claim 19, wherein the OTA comprises PMOS-NMOS transistor pairs located between P-type transistors and N-type transistors.

21. The transmit circuit of claim 20, wherein the PMOS-NMOS transistor pairs further comprise:
a first pair of transistors having a P-type transistor device and an N-type transistor device;
a second pair of transistors having a P-type transistor device and an N-type transistor device; and
the first pair of transistors and the second pair of transistors located between P-type cascode transistor devices and N-type tail transistor devices in a first stage of the OTA.

22. The transmit circuit of claim 21, wherein the first pair of transistors and the second pair of transistors in the PMOS-NMOS transistor pairs comprise respective channel lengths that are longer than channel lengths of the P-type cascode transistor devices and the N-type tail transistor devices in the first stage.

23. The transmit circuit of claim 22, wherein the PMOS-NMOS transistor pairs comprise an N-type node (Vnab) and a P-type node (Vpab) configured to provide bias signals to push-pull transistors in a second stage of the OTA in class AB operation.

24. The transmit circuit of claim 23, wherein the push-pull transistors in the second stage comprise two pairs of N-type and P-type transistors.

25. The transmit circuit of claim 19, wherein the voltage-mode BBF further comprises:
a common-mode feedback circuit configured to compare a common-mode voltage output of a second stage against a reference voltage and adjust a common-mode feedback voltage to a first stage in response to the common-mode voltage output of the second stage.

26. The transmit circuit of claim 25, wherein the common-mode feedback voltage provided to the first stage adjusts a bias voltage to push-pull transistors in the second stage to adjust a DC bias voltage output of the second stage.
